(19) United States
(12) Patent Application Publication
(10) Pub. No.: US 2018/0299498 A1
(43) Pub. Date: Oct. 18, 2018

(54) HUMAN BODY MODEL ELECTROSTATIC DISCHARGE TESTING SYSTEM AND METHODS

(71) Applicant: Evan Grund, Santa Clara, CA (US)

(72) Inventor: Evan Grund, Santa Clara, CA (US)

(73) Assignee: Grund Technical Solutions, Inc., Milpitas, CA (US)

(21) Appl. No.: 15/952,141

(22) Filed: Apr. 12, 2018

Related U.S. Application Data
(60) Provisional application No. 62/485,848, filed on Apr. 14, 2017.

(51) Int. Cl. G01R 31/00

(52) U.S. Cl. CPC G01R 31/002

(57) ABSTRACT

A test circuit and apparatus that meets requirements of Human Body Model electrostatic discharge sensitivity testing of microelectronic components that can properly test high voltage and unconnected pins is disclosed. “No Connect” pins were exempted from HBM testing by some testing standards due to prior art testers producing unintended overstress. A HBM tester has been invented that reduces this overstressing to levels were valid testing of integrated circuit No Connect pins and pins with high voltage ESD clamping protection is possible.

### CLAIM OF PRIORITY

This application claims the benefit of U.S. Provisional Application No. 62/485,848, filed Apr. 14, 2017, the entirety of which is incorporated herein by reference.

### FIELD OF THE INVENTION

Electrical circuit testing and more specifically the electrostatic discharge stress testing of integrated circuits.

### BACKGROUND OF THE INVENTION

Testing of integrated circuits (ICs) is conducted to determine the electrical characteristics or parameters of an IC or a subcircuit, such as a testable electrostatic discharge (ESD) protection circuit cell. One of the oldest and still commonly used test for IC ESD sensitivity, or ESD discharge voltage withstanding capability, is the Human Body Model (HBM) standard. Many such HBM tests have defined by electronics industry standards bodies, including the Electrostatic Discharge Association's ANSI/ESD STM5.1-2007 “For Electrostatic Discharge Sensitivity Testing—Human Body Model (HBM) Component Level”, the JEDEC Solid State Technology Association's JESD22-A 114F “Electrostatic Discharge (ESD) Sensitivity Testing Human Body Model (HBM)”, and ANSI/ESDA/JEDEC JS-001-2014 “Electrostatic Discharge Sensitivity Testing—Human Body Model (HBM) Component Level”, and the Automotive Electronics Council's AEC-Q100-Rev-H Attachment 2 AEC-Q100-002 Rev E “Failure Mechanism Based Stress Test Qualification for Integrated Circuits, Human Body Model Electrostatic Discharge Test”, and the Department of Defense's MIL-STD-883G “Test Method Standard, Microcircuits, Method No. 3015.7, ELECTROSTATIC DISCHARGE SENSITIVITY CLASSIFICATION”. There are many prior art HBM ESD testers, also called ESD simulators, meeting the requirements of these standards in use today.

Over 10 years ago several large IC device manufacturers found some of their devices were failing to reach the expected ESD withstanding voltage levels, and they traced these HBM failures to the testing of “No Connect” pins and concluded these were “false failures.” These false failures can be designated as improper test results due to damage of the device under test (DUT) that was caused by stress in excess of the prescribed HBM test, that a tester can inadvertently produce. These No Connect pins were actually not electrically connected to the actual silicon chip inside the IC package, therefore, damage to the IC when applying the HBM stress to these unconnected pins was not expected. The IC manufacturers determined that the prior art testers were producing a large, fast, high current pulses to neighboring pins of the No Connects, and that stress caused these neighbors to fail. When this information was presented to the Electrostatic Discharge Association and JEDEC standards bodies they concluded that the HBM testers were producing overstress when applying the HBM pulse to No Connects, and two standards bodies subsequently modified their HBM standard test methods to allow device testing and classifications without applying stress to the No Connect pins “until the testers can be improved so as to not produce this extra stress”. However, the HBM standards from the Automotive Electronics Council and the Department of Defense's MIL Standard for Microcircuits did not allow skipping the stressing of No Connects.

The simplified prior art HBM schematic shown in FIG. 1 is adapted from MIL-STD-883G figure 3015-1. The operation first slowly charges capacitor C1 from the REGULATED HIGH VOLTAGE SUPPLY through S1, a switch or relay in the deactivated state shown, and R1, a current limiting resistor. After C1 is charged to the voltage of the REGULATED HIGH VOLTAGE SUPPLY, V_{HBM}, then S is activated to disconnect C1 form R1 and connect C1 to the series circuit of R2 and the device under test (DUT). The connections to the DUT is shown as being made to two pins of the DUT by Tester Terminals A and B. In practice, individual DUT pins can be connected to Terminal A and Terminal B, or a single DUT pin to Terminal A and a group of DUT pins can be connected to Terminal B and stressed by a sequence of high current pulses. A stress current will flow through the DUT for a short time as C1 is discharged when S1 is activated. The typical circuit values of C1=100 pF and R2=1500Ω, were chosen by standards bodies to simulate the human body discharge.

FIG. 2 adds an important element of the practical HBM testing circuitry, the parasitic wiring capacitance to the circuit described in FIG. 1. This is the unavoidable parasitic capacitance that always exists in the pulse delivery wiring capacitance with respect to surrounding grounds (typically 30 to 40 pF, from the internal relay matrix conductors, and PCB wiring, and the test fixture board and socket, etc.), and is represented by C_{PARASITIC} in this figure for clarity. It should be understood that there is not a discrete capacitor circuit element C_{PARASITIC} but this schematic symbol represents the capacitance of all elements of the pulse delivery path. This parasitic capacitance can produce an unexpected, and undesirable, overstress to the DUT, as will be explained.

The purpose of R2 is to limit the discharge current similar to that of a person's skin and finger resistance. As described in HBM standards, the R2 resistance is located close to S1 and not between the wiring capacitance and the DUT. When applying the HBM pulse to a No Connect DUT pin, the parasitic capacitance distributed along the pulse delivery path connected to the No Connect pin is charged along with the No Connect pin by the HBM pulse current. The voltage of the parasitic capacitance and the No Connect pin will exponentially approach

$${V}_{HBM} \frac{C 1}{C 1 + {C}_{PARASITIC}} \approx 0.75 {V}_{HBM} ,$$

where V_{HBM} is the precharged voltage of C1, increasing with a time constant of

$$R 2 \cdot \frac{C 1 \cdot {C}_{PARASATIC}}{C 1 + {C}_{PARASITIC}} \approx 40 ns .$$

For example, a 2 kV HBM pulse will ramp the No Connect pin to over 1.5 kV in about 150 ns. According to Paschen's Law, at this voltage an are will occur in the space between DUT pins or balls with a pitch of 1 mm or less. (Connections to ICs are commonly termed pins, balls, tabs, contact lands, bumps, terminals, etc. These and other connections IC are collectively herein termed pins.) The arc current will discharge the parasitic capacitance, but the discharging current is not limited by any significant current limiting resistance. The discharge current will be determined by the distributed parasitic capacitance, but because this is not actually a lumped capacitor at the No Connect pin, but is more like a transmission line, the current will be limited by the effective characteristic impedance of the HBM tester wiring which will vary from <50Ω to several hundred ohms. The current from the charged parasitic capacitance can be delivered in 5 to 10 ns and has been measured to exceed 8 A on a prior art tester at 2 kV HBM.

FIG. 3 shows another style of prior art HBM pulse generation circuit that was disclosed in U.S. Pat. No. 7,560,948. In this HBM pulse generation system the capacitor C_{STORAGE} is charged to the high voltage V_{HBM} by the REGULATED HIGH VOLTAGE SUPPLY through R1. C_{STORAGE} is large, such as 10 nF, compared to the sum of C_{HBM}=100 pF plus the about 20 to 100 pF capacitance of transmission line T1. R_{T} is chosen to be close to the impedance of T1, which could be about 50Ω. T1 may be a coaxial cable with constant impedance, Z₀, or discrete wires with varying impedance, or any combination of conductors and connectors. When S2 is switched, R_{T} is connected to the voltage V_{HBM} of C_{STORAGE} so a sharp rise in voltage occurs at the left end of T1. That voltage is approximately half of the V_{HBM} because R_{T} and T1 are of approximately equal impedance and form a resistive divide

$$\frac{{Z}_{0}}{{Z}_{0} + RT} {V}_{HBM} \approx \frac{1}{2} {V}_{HBM} ,$$

where Z₀ is the impedance of T1 and is assumed to be a constant for this description. A pulse of amplitude V_{HBM}/2 is generated that propagates from the left end to the right end of T1 where it causes a rise in voltage in C_{HBM}. Since C_{HBM} and R_{HBM} are in series, and the impedance of a series resistor R_{HBM} and capacitor C_{HBM} is R_{HBM}-jX_{CHBM}, where the capacitive reactance X_{CHBM}=1/(2πf C_{HBM}) at HBM frequencies f, this pulse is terminated at the right end of T1 with an impedance magnitude of at least 1500Ω. Any pulse travelling down a transmission line will produce a reflection at its end; and the magnitude of reflection is based on the terminating impedance relative to the cable impedance and will be a fraction of the initial pulse amplitude as determined by a voltage reflection coefficient

$$Γ = \frac{{Z}_{1} - {Z}_{0}}{{Z}_{1} + {Z}_{0}} ,$$

where Z₀ is the impedance of the cable or transmission line and Z₁ is the terminating impedance. (Note in the special case where Z₁=Z₀, Γ=0 and no reflection is produced, in which case Z₁ is called a matched load.) With a cable of Z₀=50 ohms and a termination of ≥1500Ω, then Γ>0.93. When the pulse reaches the right end of T1, the voltage at that end becomes the sum of the pulse voltage plus its reflection almost doubling the voltage at the right end of T1 compared to the left end. The T1 right end voltage ≈(1+0.93)*(T1 left end voltage)=1.93*½ V_{HBM}=0.965 V_{HBM}≈V_{HBM}. Thus, the voltage of V_{HBM} that was across C_{STORAGE} is transferred to C_{HBM} when S1 is switched with only a few percent loss. The reflection generated at the right end of T1 propagates back to the left end of T1 where it is terminated by the impedance of a series resistor RT and capacitor C_{STORAGE} which is Z=R−jXc, where Xc=1/(2πfC_{STORAGE}), the capacitive reactance at frequency f. With a relatively large C and high frequency f (and very large R1), Z≈R_{T}. Therefore, T1 is terminated on the left end in almost a matched load by selecting R_{T} to equal T1 impedance, and there is no re-reflection at the left end of T1, so the voltage along T1 will then remain almost unchanging after the time required for the pulse to travel twice the length of T1. With the left side of C_{HBM} held at V_{HBM} by C_{STORAGE} and R2 and T1, current flows through C_{HBM} and R_{HBM} and through transmission line T2 to the DUT, generating the standard HBM stress pulse at the DUT pins. Note that the parasitic capacitance, diagrammed as C_{PARASITIC}, appearing across the DUT pins is from the capacitance of T2 and other tester wiring. Like T1, T2 may be a coaxial cable with constant impedance, or discrete wires with varying impedance, or any combination of conductors and connectors. The parasitic capacitance in HBM pulse generating circuit FIG. 3 will produce a similar extra stress when an HBM pulse is applied to a No Connect pin as the circuit diagrammed in FIG. 2 or other HBM pulse generating circuits.

High voltage ICs, for example those with silicon controlled rectifier (SCR) power rail clamping, also allow charging of the parasitic capacitance to a significant high voltage before substantial current flows through the stressed pin. For example, with typical DUT test fixture board line impedance of approximately 75 ohms, an SCR protection subcircuit that has a trigger (turn-on) voltage in excess of 50 V can deliver the peak current of a 1 kV HBM pulse from a 125 V HBM pulse. An arc between DUT pins is not always needed to produce undesired extra stress because the ESD protection circuitry can also switch on quickly and support fast high current spikes at voltages lower than are required for arcs to occur. Thus, the prior art tester parasitics can produce overstress pulses to connected DUT pins in addition to the No Connect type of DUT pins.

The result of the fast discharge of the parasitic HBM tester capacitance is a large current spike that produces stress beyond that intended by the HBM testing standards. Therefore, a need exists in the art of IC testing to HBM standards to remove the high current spikes of parasitic capacitance discharges that occur from arcing between IC pins or fast turn-on of high voltage ICs. To meet all testing standards and allow stressing of all pins without producing false failures an improved HBM tester is needed.

### SUMMARY OF THE INVENTION

Accordingly, it is an object of the present invention to provide a Human Body Model ESD tester that meets the specifications of testing standards bodies including the ability to apply the HBM stress to IC or module pins, balls, pads or other terminals that may not be connected to the actual circuitry inside IC or microelectronics module package. A root cause of improper stress testing by prior art HBM testers has been determined to be caused by electrical arcing between a “No Connect” type pin that is being stressed and one of its neighboring pins. The current flow during this arc can be many times greater than the normal and expected HBM stress current. No Connects are pins, balls, lands, bumps or other terminals types provided in microelectronic packaging that are not electrically connected to the circuitry inside the package.

A key element of a prior art HBM tester is a series current limiting resistance of 1500 ohms that roughly represents the human body resistance. While an HBM tester produces a high voltage, often thousands of volts, to simulate an ESD discharge, the stress current applied to the DUT is typically limited to a few amperes or less due this series resistance. If an IC pin does not have a current carrying circuit attached to it that acts to limit the applied high voltage, current will flow through the 1500Ω resistor and charge the pin and tester wiring to a voltage that can be almost as high as the HBM test voltage. The voltage across a gap of a few tenths of a millimeter between the No Connect pin being stressed and one of its neighboring pins can reach a potential that produces an arc across the gap. This invention limits the current of such arcs by redistributing the 1500 ohms of series resistance and/or increasing the impedance of the pulse delivery path.

These and other objects, features and advantages of the present invention will no doubt become apparent to those skilled in the art after reading the following detailed description of the preferred embodiments that are illustrated in the several accompanying drawings.

### BRIEF DESCRIPTIONS OF DRAWINGS

The present invention can be better understood with reference to the following drawings. The components within the drawings are not necessarily to scale relative to each other, nor are their electrical values exact, emphasis instead being placed upon clearly illustrating the principles of the present invention.

FIG. 1 is a simplified schematic diagram of a prior art HBM pulse generator circuit as presented in HBM Standard document MIL-STD-883G.

FIG. 2 is the schematic diagram of FIG. 1 extended to show the parasitic capacitance of a prior art tester diagrammed as a lumped circuit element representing the distributed capacitance from several sources that comprise the tester wiring, including capacitance from a relay switching matrix used when the DUT has a multiplicity of pins.

FIG. 3 is an alternate prior art HBM pulse generator circuit.

FIG. 4 is a preferred embodiment of the invention wherein the series resistance of 1500 ohms, in a circuit like depicted in FIG. 2, is divided and distributed where part of that series resistance is positioned close to the DUT to limit the current of arc discharges.

FIG. 5 is another preferred embodiment of the invention wherein the series resistance of 1500 ohms of a HBM pulse generation circuit, like depicted in FIG. 3, is divided and distributed with part of the series resistance positioned on each side of the DUT.

FIG. 6 is a preferred embodiment of the invention that includes a probe card which is commonly used in testing ICs in their pre-packaged wafer form and apparatus for recording the HBM stress applied.

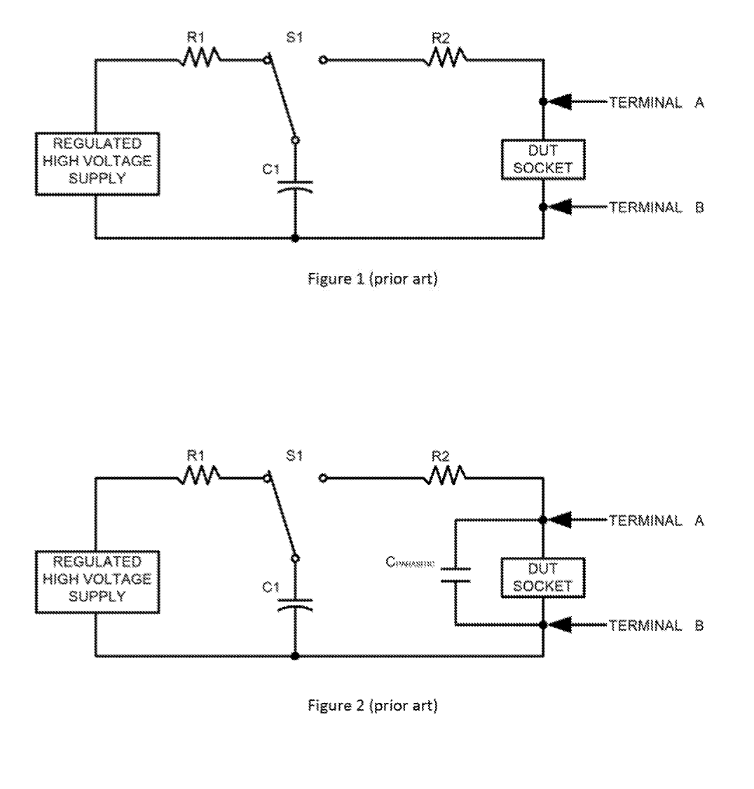

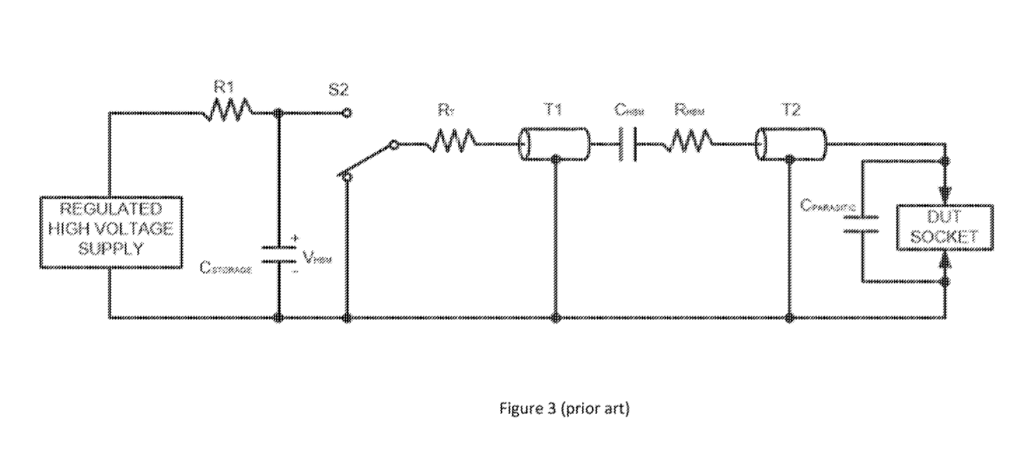

### DETAILED DESCRIPTION OF THE DRAWINGS

In the following description, numerous specific details are provided, such as the identification of various system components and their approximate values, to provide a thorough understanding of embodiments of the invention. One skilled in the art will recognize, however, that the invention can be practiced without one or more of the specific details, or with other methods, components, materials, etc. In still other instances, well-known structures, materials, or operations are not shown or described in detail to avoid obscuring aspects of various embodiments of the invention. Reference throughout this specification to “one embodiment” or “an embodiment” means that a particular feature, structure, or characteristic described in connection with the embodiment is included in at least one embodiment of the present invention. Thus, the appearance of the phrases “in one embodiment” or “in an embodiment” in various places throughout this specification are not necessarily all referring to the same embodiment. Furthermore, the particular features, structures, values, or characteristics may be combined in any suitable manner in one or more embodiments.

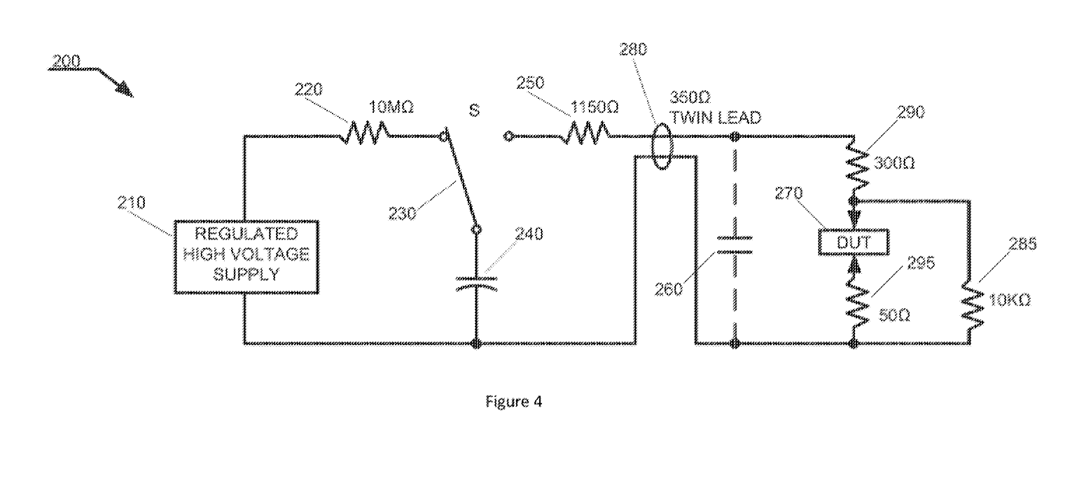

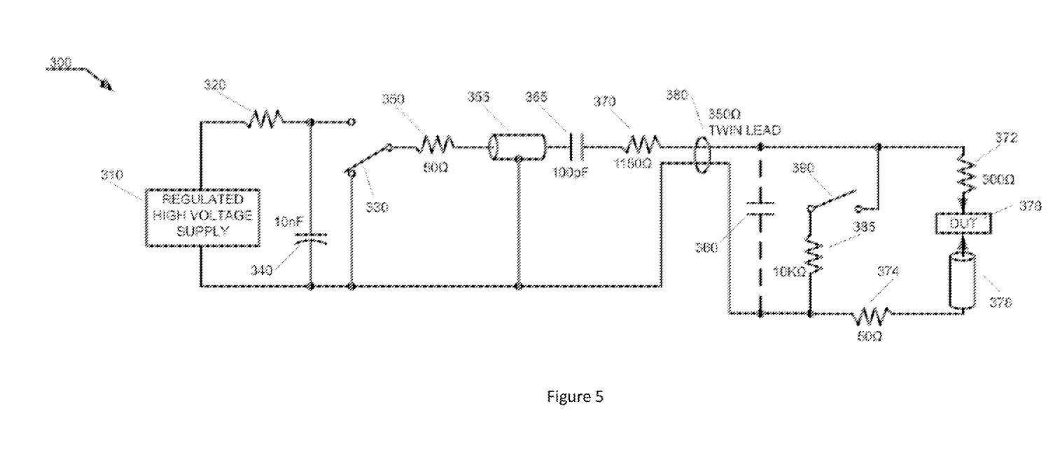

A feature of this invention is to reduce the stress from the sudden discharge of parasitic delivery wiring capacitance into the DUT. One method of this invention is to introduce current limiting resistance between the parasitic wiring capacitance and the DUT. Another method is to modify the HBM tester delivery wiring to increase its characteristic impedance. While each method can be practiced independently, the circuit 200 as shown in FIG. 4 is a preferred embodiment using both these two methods.

The pulse delivery path from the pulse generator to the DUT may be discrete wires, a cable of coaxial or twin lead or other construction, a printed wiring board, or a combination of these and/or other conduction means along with various types of circuit connectors. The aggregate capacitance of this delivery path wiring can store energy if the DUT allows the HBM voltage to rise to a significant level before the DUT begins to conduct. An ESD protection circuitry is often added to IC inputs to conduct ESD discharge currents, and thereby limit the voltage applied to pins because a portion of that applied voltage may reach sensitive internal IC circuitry. One method of this invention is to limit the current that can stress the DUT by adding resistance between the wiring capacitance and DUT pin. Required to meet the definition of an HBM tester per the referenced standards, the pulse generator output resistance must be 1500 ohms. That total resistance requirement is met in this invention, but not all of the 1500 ohms is retained in the HBM pulse generator proper; part of the required 1500 ohms is moved from the pulse generator to the DUT location, while maintaining a total of 1500 ohms. This limits in inrush current when the DUT initiates conduction of the ESD pulse.

Typical prior art HBM testers utilize standard cables and/or printed wiring board traces for pulse path construction which results in impedances from 50 to 100 ohms. Increasing the impedance of the delivery path provides two advantages in reducing DUT overstress: 1) increased impedance limits the instantaneous current that can be carried by the wiring for a given voltage, and 2) the capacitance of the wiring is inversely proportional to the square root of the impedance and lower capacitance stores less energy for a given voltage.

As shown in FIG. 4, the Regulated High Voltage Supply 210 will charge the HBM capacitor 240 through resistor 220 and switch 230, shown in its deactivated state. When activated switch 230 will connect capacitor 240 to DUT 270 through delivery path 280 and series resistors 250, 290 and 295. The parasitic wiring capacitance, diagrammed as capacitor 260, can be discharged through DUT 270, but is current limited by resistance of resistors 290 and 295. In this embodiment, the HBM pulse is carried to the DUT via a wiring path that is mainly composed of twin lead (two wires held at an approximately constant distance) with an approximately constant impedance of about 300 to 350 ohms. It is desired to make the impedance as high as possible to limit an arc discharge current, and a pair wires with a constant spacing of about one-third inch with mostly air dielectric between them can produce the high twin lead impedance (Z₀) approaching 350 ohms. To provide an almost matched termination (as explained above), and thereby reduce pulse ringing from reflections, the sum of resistors 290 and 295 is selected to match the twin lead Z₀. The resistance of resistor 295 can be selected to be 50 or 75 ohms as these are commonly used termination resistors, and with resistor 295 being 50 ohms, resistor 290 is therefore 300 ohms in this embodiment. While these are convenient values, these resistance values can be changed significantly in this invention as long as the sum of resistors 250 plus 290 plus 295 approximately totals 1500 ohms.

The path 280 may be construct from coaxial cable which have characteristic impedances ranging from about 75 to 93 ohms, or from twin lead wires with impedances from 100 to 350 ohms. A common example of twin lead wires is 300-ohm TV antenna lead which was popular for many years of analog TV broadcast reception.

In practicing this invention, the current limiting resistances 290 and 295 can be on placed on both sides of DUT 270 or on a single side, such as having either 290 or 295 be zero ohms. Also, the resistances of 290 and 295 can be equal, or unequal as shown in example circuit 200. One variation of this embodiment would be to use only resistor 290, making resistor 295 equal to zero ohms. In this variation resistor 290 would become approximately 350 ohms.

Some HBM standards suggest that a resistance should be switched in to provide a discharge path for the DUT to remove injected charge after the HBM stress is applied. In circuit 200 this discharge is provided by resistor 285. In practice, the resistor 285 can be switched into contact with DUT 270 only after each HBM pulse or permanently connected as shown. Suggested values for resistor 285 are from 10Ω to 1 MΩ.

Another preferred embodiment is circuit 300 as diagrammed in FIG. 5. The Regulated High Voltage Supply 310 will charge the storage capacitor 340 through resistor 320. Capacitor 340 is large, such as 10 nF, compared to the sum of capacitor 365 (100 pF as defined in the HBM specifications) plus the capacitance of transmission line 355. Resistor 350 is chosen to be close to the impedance of transmission line 355, which could be about 50Ω for both. Transmission line 355 may be a coaxial cable with constant impedance, Z₀, or discrete wires with varying impedance, or any combination of conductors and connectors. When Switch 330 is activated, transmission line 355 is connected to the voltage V_{HBM} of capacitor 340 so a sharp rise in voltage occurs at the left end of transmission line 355. That voltage is approximately half of the V_{HBM} because R350 and transmission line 355 are of approximately equal impedance and form a resistive divider

$$\frac{{Z}_{0} 355}{{Z}_{0} 355 + R 350} {V}_{HBM} \approx \frac{1}{2} {V}_{HBM}$$

where Z₀ 355 is the impedance of transmission line 355 and is assumed to be a constant for this description and R350 is the resistance of resistor 350. The rising edge of a pulse of amplitude V_{HBM}/2 that propagates from the left end to the right end of transmission line 355 where it causes a rise in voltage in capacitor 365. Since capacitor 365 and resistor 370 are in series, this pulse travelling along transmission line 355 is terminated at the right end of transmission line 355 in an impedance greater than R₃₇₀−j X_{C365}, where X_{C365}=1/(2πfC₃₆₅) at HBM frequency f, and with resistor 370=1500Ω the termination impedance ≥1500Ω. Any pulse travelling down a transmission line will produce a reflection at its end, unless terminated in a match load as explained above. The magnitude of this reflection is determined by voltage reflection coefficient

$$Γ = \frac{{Z}_{TERM} - {Z}_{0} 355}{{Z}_{TERM} + {Z}_{0} 355} > 0.93 , where {Z}_{0} 355 = 50 Ω$$

is the impedance of the transmission line and Z_{TERM}>1500Ω is the terminating impedance. Thus, when pulses reach the right end of transmission line 355, the voltage at that end becomes the pulse voltage plus its reflection, almost doubling the voltage at the right end of transmission line 355 compared to the left end at that moment. The transmission line 355 right end voltage ≈(1+0.93)*(transmission line 355 left end voltage)=1.93*½V_{HBM}=0.965 V_{HBM}≈V_{HBM}. Thus, the voltage of V_{HBM} that was across capacitor 340 is roughly transferred to capacitor 365 when switch 330 is activated with only a few percent loss. The reflection generated at the right end of transmission line 355 propagates back to the left end of transmission line 355 where it is terminated by impedance Z of resistor 350 and series capacitor 340. With a relatively large capacitor 340, and high frequency f, Z≈50Ω. Therefore, transmission line 355 is terminated on the left end in almost a matched load by selecting resistor 350 approximately equal to transmission line 355 impedance, and there is no re-reflection at the left end of transmission line 355, so the voltage along transmission line 355 will then remain almost unchanging. With the left side of capacitor 365 held at V_{HBM} by capacitor 340 and resistor 350 and transmission line 355, current flows through capacitor 365 and resistor 370 and through transmission line 380 to the DUT generating the standard HBM stress pulse sourced from the stored energy in capacitor 340. In this embodiment, the parasitic wiring capacitance from 380 and other tester wiring, diagrammed as capacitor 360, is isolated from the DUT 375 and current limited by resistors 372 and 374. Transmission line 378 is used as convenient wiring and may be a coaxial cable with constant impedance, or discrete wires with varying impedance, or any combination of conductors and connectors. To preserve the HBM pulse quality, the impedance of transmission line 378 and resistance of resistor 374 are of similar values.

For practical application of HBM testing, it is required to move the HBM tester connections to different DUT pins. To accomplish that motion easily, flexible cables or twin leads, or other flexible circuitry, is used for transmission lines 355, 380 and 378. The parasitic capacitance of 380 is a major source of stored charge that may produce an overstressing current spike. The overstressing current can be reduced by increasing the characteristic impedance of the delivery path 380. This embodiment uses a twin lead with two wires spaced an approximately constant distance of 0.3 to 0.5 inches apart to have an impedance of 300 to 350 ohms. To minimize ringing, reflections around DUT 375 should be avoided, and 380 should be terminated by a match load as previously explained. This is accomplished when the sum of resistors 372 and 374 are selected to be approximately the same resistance as the impedance of twin lead 380 and resistors 372 and 374 are placed close to the DUT 375. It should be understood that typical DUT impedances are low by IC designs to avoid ESD pulse damage. 10025J In this embodiment, the only resistor that needs to be placed very close to DUT 375 is resistor 372. This is because cable 378 is added in series between the DUT 375 and resistor 374, and values are selected to have transmission line 378 to have the same impedance as the resistance of resistor 374. When a cable of constant impedance is terminated in a match load (same impedance) that combined cable and termination has the same load as a single resistor of the common impedance. Therefore, the cable 378 can be of any convenient length when added between the DUT 375 and resistor 374 with the same effect on the HBM waveform as having no cable. 50 and 75 ohms are convenient choices for 374 and 378 values.

Some HBM standards specify an additional discharge path to be provided to discharge the DUT after the HBM stress pulse. Resistor 385 and switch 390 perform this function. After an HBM pulse has been completed, switch 390 is activated to connect resistor 385 to provide a discharge path across the DUT 375 and DUT connecting resistors. A discharge path can be made directly across DUT 375 or through other resistors connected to DUT 365. As shown in this embodiment, resistor 385 is connected by switch 390 to one side of the DUT 375 through resistor 372 and through resistor 374 and cable 378 to the other side of the DUT 375. A number of different discharge paths could be used as the path through either or both resistor 372 or 374 or cable 378 could be avoided by more direct connections.

The embodiment of circuit 300 will generate and apply a second HBM pulse of opposite polarity to DUT 375 when the switch 330 is returned to it deactivated position. The operation generating this second pulse is identical to the operation of the first pulse as just described with opposite polarities of voltages and currents.

It should now be understood that the parasitic capacitance that can be charged by the HBM pulse current which can produce a high current unwanted stress to the DUT can be significantly reduced by the methods of this inventions.

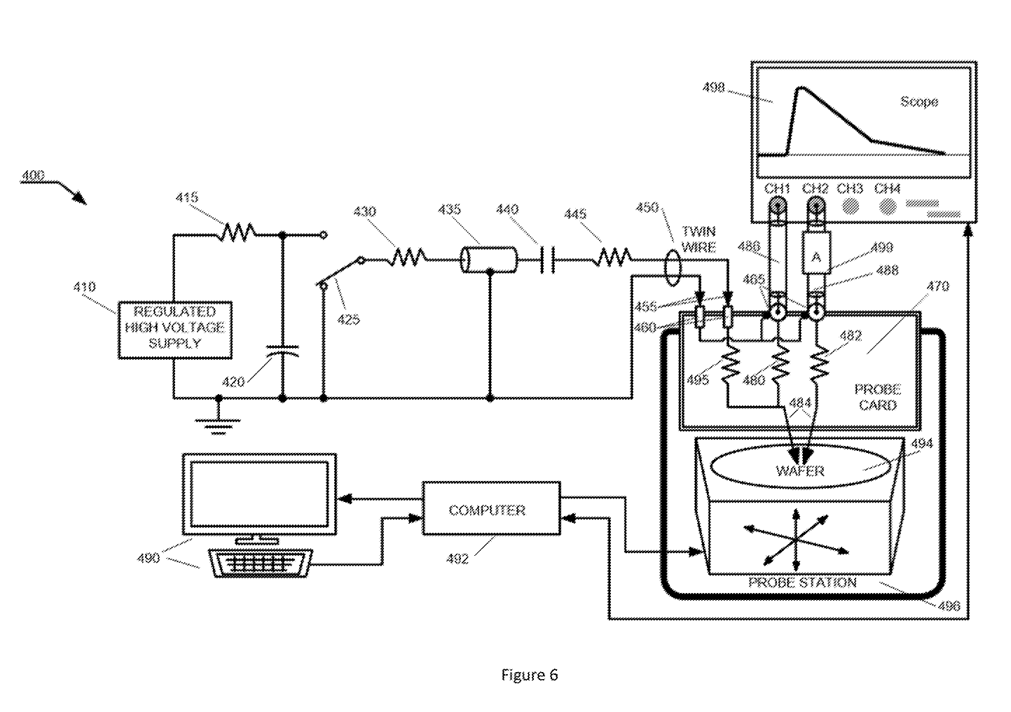

The HBM testing system 400 diagrammed in FIG. 6 is a preferred embodiment that allows proper testing of a IC circuit or IC subcircuit DUT that is part of semiconductor wafer. A wafer 494 is typically a substrate upon which micro-circuitry is fabricated with electrical contact pads which are connected to the DUTs. The wafer is often held by a probe station 496 that adjusts the wafer relative to a probe card 470 which is held by the probe station 496 in a position relative to the wafer. Operation of the probe station 496 and other equipment in this system is controlled by computer 492 with human interface components 490. Testing can be controlled by the computer 492 under direction of a user and can provide test results to a user.

The HBM pulse is generated after the Regulated High Voltage Supply 410 has charged the storage capacitor 420 through resistor 415 to a voltage V_{HBM}. When activated, switch 425 will connect capacitor 420 to resistor 430 and the voltage V_{HBM} across capacitor 420 will cause a sharp rise in voltage across the resistor 430 and at the left end of transmission line 435. The voltage V_{HBM} will be transferred to capacitor 440 by the operation of the transmission line 435 terminated at its left end by 410, 415, 420 and 430 and on its right end by 440, 445, 450 and circuitry around the DUT as explained by the similar operation in circuit 300 of FIG. 5. Thus, when switch 425 is activated, HBM pulse current will flow from capacitor 420 through capacitor 440, through resistor 445, through twin lead 450 (also carrying the ground return circuit path), through a pair of contacts 455 to connecting pads 460 on probe card 470, through resistor 495 and through probe needle pair 484 to DUT on wafer 494. The connection between resistors 445 and 495 can be made by soldered wires or spring loaded connectors such as pogo pins 455 to probe card 470 pads 460. The HBM waveform is maintained by having capacitor 440 be approximately 100 pF and series resistors totaling 1500 ohms. The series resistors are 445, 495, 482 and the combination of cable 488 and input impedance of oscilloscope 498. The total resistance of these resistors should be close to 1500 ohms. The input impedance of oscilloscope 498 should be 50 ohms and cables 486 and 488 should be matching 50 Ω cables. Together the cables 486 and 488 and oscilloscope 498 appear as 50Ω resistances when connected to probe card 460 at connectors 465 because they are constant impedance cables terminated by match loads as previously described. Attenuator 499, that may be added in series with the cable 488, is a 50-ohm attenuator that maintains the constant impedance while reducing the signal voltage to levels compatible with oscilloscope 498. As the HBM current flows through capacitor 440 and resistances, cables and connectors 445, 450, 455, 495, 482, 465, 488, attenuator 499 and oscilloscope 498, it also flows through wafer probes 484 and through DUT circuit on wafer 494. The impedance of wires 450 should be approximately equaled by the sum of resistances of resistors 495, 482 and the 50Ω oscilloscope input impedance so they provide a matched load. Resistance 482 may be zero; if non-zero the signal to the oscilloscope is attenuated and the series resistances need adjustment to total 1500Ω.

The pulse current return circuit path from the DUT to the lower connections of both the Regulated High Voltage Supply 410 and capacitor 420, that circuit node being identified by a ground symbol, is the path through wafer probe 484, resistor 482 on probe card 470, cable 488, attenuator 499 and oscilloscope 50 Ω input. The oscilloscope input has a reference ground on its inputs that connects to the shield of attached cables. The cable shields of both 486 and 488 provide a ground return path to the probe card 470 ground which connects to the ground return of twin wire 450, and to the ground node of capacitor 420 and Regulated High Voltage Supply 410.

The HBM pulse current waveform, I_{DUT}(t), can be measured as a voltage recording on the oscilloscope 498 with the relationship of I_{DUT}(t)=A*V_{SCOPE}(t)/(R_{C1}+50), where R_{C1} is the resistance of resistor 482, and A=attenuation factor of attenuator 499 (if attenuator 499 is not used then A=1). An attenuator 499 of 34 or 40 dB (A=50 or 100, respectively) can be used as needed to reduce the pulse level to voltages that are safe for the oscilloscope input (typically 5 V maximum).

The voltage waveform, V_{DUT}(t), across the DUT can be measured as a difference of voltage recordings on two oscilloscope channels with the relationship of V_{DUT}(t)=50*V_{Ch1}(t−t₁)/(50+R₃)−50*A*V_{Ch2}(t−t₂)/(50+R_{C1}), where V_{Ch1} is the oscilloscope channel connected to cable 486, and V_{Ch2} is the oscilloscope channel connected to cable 488, and R₃ is the resistance of resistor 480, and R_{C1} is the resistance of resistor 482, and t1 and t2 are propagation times through cables 486 and 488 respectively, and A=attenuation factor of an attenuator in series with cable 488 if any, else A=1. R₃ resistor 480 is connected to the resistor 475 and a DUT pad for measuring the voltage at that DUT pad.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that all claims be interpreted as covering all alternations and modifications as fall within the true spirit and scope of the invention.

What is claimed:

1. A testing circuit and method that applies a pulse with characteristics described in a published Human Body Model electrostatic discharge simulation standard to terminals of a device under test by current conducted by a capacitor and series resistance of approximately 1500 ohms, wherein multiple discrete resistances in aggregate constitute said series resistance, and one or two of these resistances are placed in close electrical communication with the device under test terminals.

2. The testing circuit and method of claim 1 that further includes the use of a switch or relay that controls the charging and discharging of said capacitor.

3. The testing circuit and method of claim 1 that further includes conductors between said discrete resistances with characteristic impedances greater than 100 ohms.

4. The testing circuit and method of claim 3 wherein resistance values of said discrete resistances in close electrical communication with the device under test terminals in sum approximately match the impedance of said conductors.

5. The testing circuit of claim 1 that further includes a conduction path from the device under test to the circuit ground constructed with a controlled characteristic impedance path of 100 ohms or less with a matching resistive termination.

6. The testing circuit of claim 1 that further includes a discharge conductive path of 10 kiloohms or higher between the terminals of the device under test.

7. The testing circuit of claim 6 wherein one or more of the said series resistances and/or conductors are included in said discharge conductive path.

8. The testing circuit of claim 6 wherein a switch or relay operable after application of said pulse is included in said discharge conductive path.

9. The testing circuit and method of claim 3 further including conduction paths formed from printed wiring boards and probe needles that make contact to devices under test terminals.

10. The testing circuit and method of claim 9 where one or more of the said discrete resistances are placed upon said printed wiring board.

11. The testing circuit and method of claim 9 that include probe stations to position said printed wiring boards relative to the device under test terminals under computer control.

12. The testing circuit and method of claim 3 that further includes an oscilloscope and connecting components to record a measurement of the current passing through the device under test as a function of time during said pulse.

13. The testing circuit and method of claim 3 that further includes an oscilloscope and connecting components to record a measurement of the voltages at said device under test terminals as a function of time during said pulse.
